(19) United States
(12) Patent Application Publication
(10) Pub. No.: US 2007/0026658 A1
(43) Pub. Date: Feb. 1, 2007

(54) Process of forming an as-grown active p-type III-V nitride compound

(76) Inventors: Chia-Ming Lee, Toucheng Township (TW); Tsung-Liang Chen, Nantou City (TW)

Correspondence Address: David I. ROCHE;BAKER & McKENZIE LLP, 130 E. Randolph Drive, Chicago, IL, 60601, US

(21) Appl. No.: 11/194,163

(22) Filed: Aug. 1, 2005

(51) Int. Cl. H01L 21/28; H01L 21/302

(52) U.S. Cl. 438/604; 438/689; 257/E33.023

(57) ABSTRACT

In a method of forming an as-grown active p-type III-V nitride compound layer, a substrate is introduced and heated in a reaction chamber. N₂ carrier gas and reactive compounds including a source compound of a group III element, a nitrogen source compound, and a p-type impurity are fed in the reaction chamber. A chemical reaction occurs to form an as-grown active p-type III-V nitride compound layer.

### FIELD OF THE INVENTION

The present invention generally relates to the manufacture of III-V nitride compounds, and more particularly to a process of forming an as-grown active III-V nitride compound that does not require a separate activation process.

### DESCRIPTION OF THE RELATED ART

III-V nitride compounds such as gallium nitride (GaN) are broadly used in the manufacture of light-emitting devices. The layer structure of the light-emitting device comprises a light-emitting layer sandwiched between n-type and p-type layers. The light-emitting layer is configured to irradiate light in response to an electric signal applied between electrodes of the light-emitting devices. The electric stimulation creates an injection of electrons and holes from the n-type and p-type semiconductor layers into the light-emitting layers where they recombine to produce light.

Generally, a technique of metal-organic vapor phase epitaxy (MOVPE) deposition is implemented to manufacture the light-emitting device, such as described in U.S. Pat. No. 6,830,992, the disclosure of which is incorporated herein by reference. According to this technique, gaseous substances including H₂ as carrier gas, ammonia NH₃, trimethyl gallium (“TMGa”) and silane (SiH₄) are introduced in a heated reaction chamber to form an n-type GaN layer over a sapphire substrate. SiH₄ can be used as source of Si impurity injected to confer the n-type conduction. A buffer layer may be also interposed between the n-type GaN layer and the sapphire substrate to balance their mutual lattice mismatch. One or more light-emitting layers then are deposited on the n-type GaN layer, followed with forming a p-type GaN layer thereon. The growth technique introduces gaseous substances including H₂ as carrier gas, NH₃ and trimethyl gallium (TMGa hereinafter), with doping impurities such as Mg, Zn, Cd, Be or the like, in the reaction chamber to form the p-type GaN layer.

However, the as-grown p-type GaN layer does not exhibit adequate p-type conduction. Indeed, hydrogen atoms may bond to the doping impurities during the layer growth process, which prevents the p-type impurities from acting as acceptors. As a result, a subsequent activation process such as an annealing step is necessary to break the hydrogen bonds and thereby free the acceptor impurities. As described in U.S. Pat. No. 5,468,678, the disclosure of which is incorporated herein by reference, the annealing process is usually conducted under specific conditions of temperature, pressure and gaseous environment in a furnace to activate the p-type GaN layer.

Subsequent to the annealing process, a transparent conductive layer made of materials such as indium tin oxide is also formed on the p-type GaN layer. The transparent conductive layer is formed to compensate the relatively poorer conduction of the p-type GaN layer.

The requisite annealing step applied to activate the p-type GaN layer constitutes an additional thermal cost. Further, the annealing process applied to activate the p-type GaN layer may adversely modify the lattice structure of other layers previously formed on the substrate, which may be detrimental to the device performance.

### SUMMARY OF THE INVENTION

The present application describes a process of forming an as-grown active p-type III-V nitride compound layer without requiring a separate activation process.

In an embodiment, a process of forming an active p-type III-V nitride compound layer comprises introducing N₂ carrier gas in a reaction chamber where a substrate is placed at a reaction temperature, and introducing at least one source compound of a group III element, one nitrogen source compound, and a p-type impurity in the reaction chamber, whereby a chemical reaction occurs to form an active p-type III-V nitride compound layer.

In some embodiments, the reaction temperature is above about 400° C. In some embodiments, the at least one source compound of a group III element includes trimethyl gallium, triethyl gallium, trimethyl indium, trimethyl aluminum, or the like. In one embodiment, the nitrogen source compound includes ammonia NH₃. In some embodiments, the p-type impurity includes Mg, Zn, Cd or the like.

In a variant embodiment, the process further includes forming an initial p-type III-V nitride compound layer by using a second carrier gas different from N₂ before introducing N₂ carrier gas in the reaction chamber. In some embodiments, the second carrier gas includes H₂. In some embodiments, the buffer p-type III-V nitride compound layer is formed at a temperature above about 400° C.

According to another embodiment, a process of forming an active p-type III-V nitride compound layer comprises introducing a carrier gas of a first composition, at least one source compound of a group III element, one nitrogen source compound, and a p-type impurity in a reaction chamber where a substrate is placed at a reaction temperature, whereby a chemical reaction occurs to form a p-type III-V nitride compound layer, and changing the carrier gas from the first composition to a second composition different from the first composition while forming the p-type III-V nitride compound layer. The p-type III-V nitride compound layer is thereby grown in an active state.

In some embodiments, at least one of the first and second compositions of the carrier gas includes N₂. In some embodiments, at least one of the first and second compositions of the carrier gas includes H₂. In some embodiments, the reaction temperature is above about 400° C.

The foregoing is a summary and shall not be construed to limit the scope of the claims. The operations and structures disclosed herein may be implemented in a number of ways, and such changes and modifications may be made without departing from this invention and its broader aspects. Other aspects, inventive features, and advantages of the invention, as defined solely by the claims, are described in the non-limiting detailed description set forth below.

### BRIEF DESCRIPTION OF THE DRAWINGS

FIG. 1 is a schematic view of an exemplary MOVPE reactor used to implement an embodiment of the invention;

FIG. 2A is a schematic view illustrating a process of cleaning a substrate according to an embodiment of the invention;

FIG. 2B is a schematic view illustrating a process of forming an n-type GaN layer in the manufacture of a light-emitting device according to an embodiment of the invention;

FIG. 2C is a schematic view illustrating a process of forming a light-emitting layer in the manufacture of a light-emitting device according to an embodiment of the invention;

FIG. 2D is a schematic view illustrating a process of forming an as-grown active p-type GaN layer in the manufacture of a light-emitting device according to an embodiment of the invention;

FIG. 2E is a schematic view illustrating a process of forming a transparent conducting layer in the manufacture of a light-emitting device according to an embodiment of the invention;

FIG. 2F is a schematic view illustrating a process of forming contact pads in the manufacture of a light-emitting device according to an embodiment of the invention;

FIG. 3A is a schematic view of a process of forming an as-grown active p-type GaN layer according to another embodiment of the invention;

FIG. 3B is a schematic view of a light-emitting device fabricated according to another embodiment of the invention;

FIG. 4A is a schematic graph plotting the light intensity level emitted from light-emitting devices respectively fabricated with and without an activation step of a p-type GaN-based layer;

FIG. 4B is a schematic graph plotting the operation voltage of light-emitting devices respectively fabricated with and without an activation process of a p-type III-V nitride compound layer; and

FIG. 4C plots light intensity curves obtained for light-emitting devices respectively fabricated with and without an activation process of a p-type III-V nitride compound layer.

### DETAILED DESCRIPTION OF THE EMBODIMENT(S)

The application describes a technique of forming an as-grown p-type III-V nitride compound layer and its implementation in the manufacture of, for example, light-emitting devices.

In this description, “III-V nitride compound layer” means a layer made of a compound including a group V nitride element and a group III element such as Ga, Al and In, which can be expressed by the general formula AlₓIn_{y}Ga_{(1-x-y)}N, wherein x, y and (1-x-y) are respectively in the range of [0, 1]. Typical III-V nitride compounds include GaN, AlGaN, InGaN, AlInGaN, etc.

“As-grown active p-type III-V nitride compound” means the p-type III-V nitride compound is grown in an active state, so that no additional annealing step or like activation process is required.

Suitable methods for forming the III-V nitride compound layer include vapor phase growth techniques such as a metal-organic vapor phase epitaxy (MOVPE) growth deposition, a molecular beam epitaxy (MBE) growth deposition, a hydride vapor phase epitaxy (HVPE) growth deposition or the like. According to this invention, a vapor phase growth technique is implemented to form an active p-type III-V nitride compound layer. The inventors of this application have found that a p-type III-V nitride compound layer can be grown in an active state in specific carrier gas conditions, so that no additional annealing step or like activation step is required.

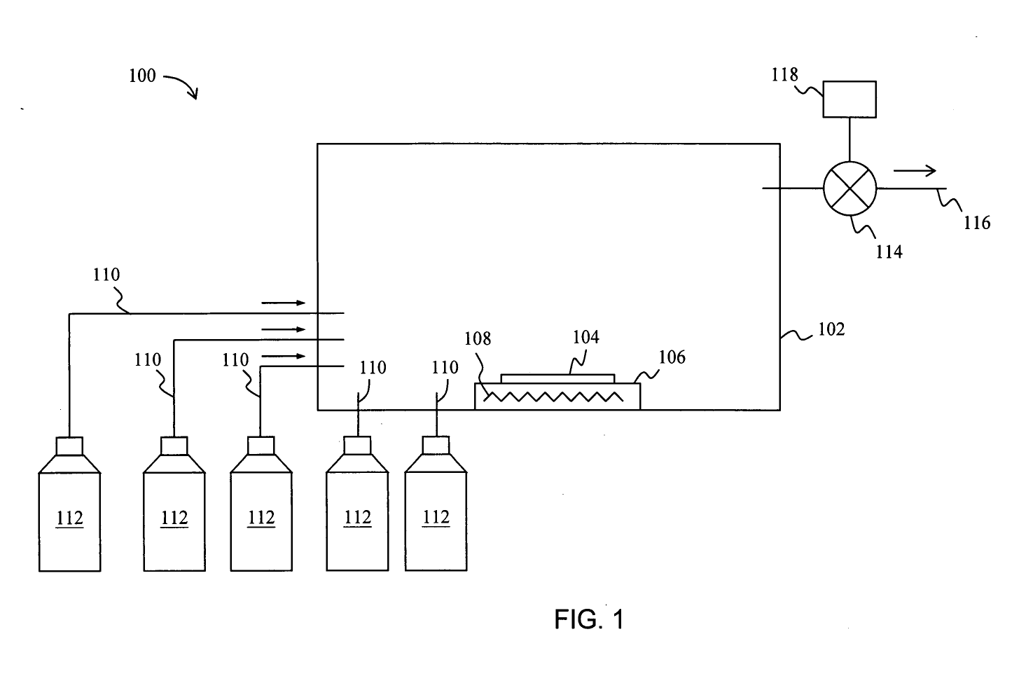

FIG. 1 is a schematic view of a MOVPE reactor implemented in a process of forming an as-grown active p-type III-V nitride compound layer according to an embodiment of the invention. The reactor 100 includes a reacting chamber 102 in which a substrate 104 is placed on a susceptor 106 to undergo a deposition process. A heating device 108 is mounted to the susceptor 106 to heat the substrate 104. Gaseous chemicals are introduced into the reacting chamber 102 via inlet tubes 110 respectively connecting to containers 112. A mechanical pump 114 is operable to discharge gases out of the reacting chamber 102 through an outlet tube 116. In addition, a control and regulating mechanism 118 connects to the mechanical pump 114 to regulate the pressure inside the reacting chamber 102.

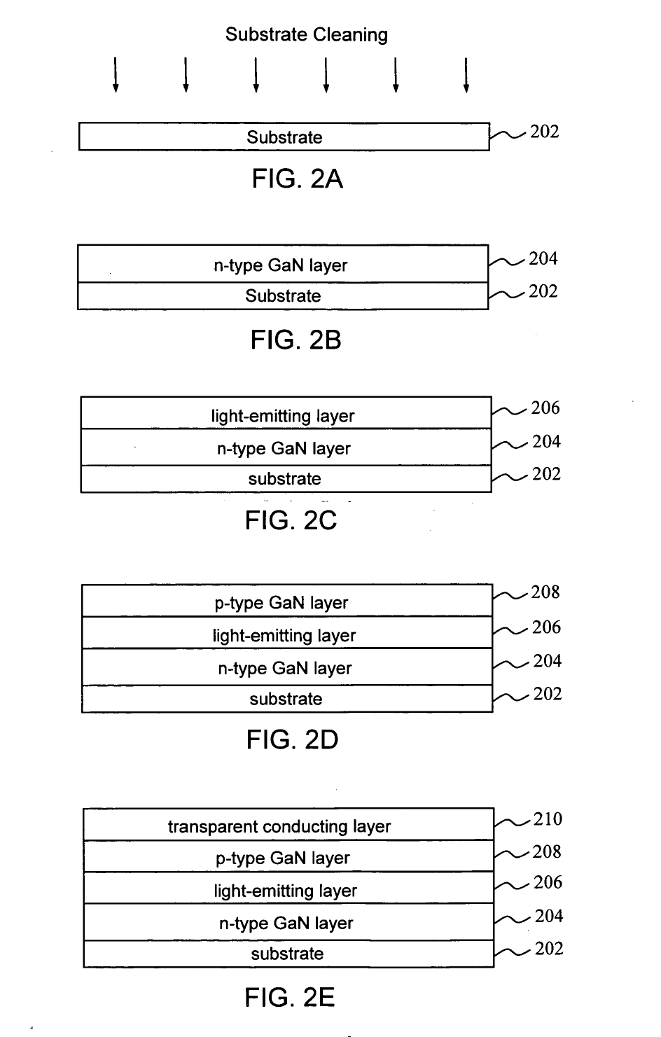

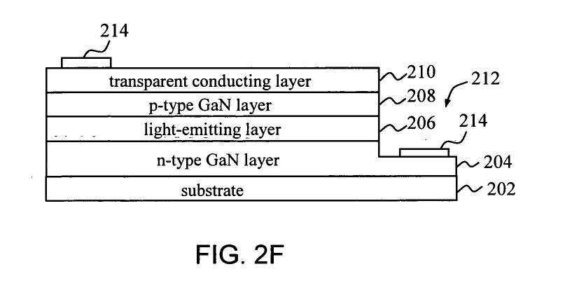

FIGS. 2A through FIG. 2F are schematic views of a manufacture process of a light-emitting device implementing a growth technique that forms an as-grown active p-type III-V nitride compound layer according to an embodiment of the invention. In FIG. 2A, a transparent substrate 202 undergoes an organic cleaning and heat treatment. The substrate 202 can be made of sapphire.

Referring to FIG. 2B, an n-type GaN layer 204 is formed on the substrate 202. The n-type GaN layer 204 is formed by a metal-organic vapor phase epitaxy deposition in which H₂ carrier gas and reactive compounds including trimethyl gallium (TMGa) or triethyl gallium (TEGa), ammonia (NH₃) and silane are fed in the reaction chamber, the substrate 202 being heated at a temperature of about 1100° C. A buffer layer (not shown) comprised of AlN may be interfaced between the n-type GaN layer 204 and the substrate 202 to compensate a lattice mismatch between these two layers. Should the n-type layer 204 be made of a compound other than GaN, such as InGaN or AlGaN and the like, the chemical mixture can accordingly include additional reactive compounds such as trimethyl indium and trimethyl aluminum and the like.

Referring to FIG. 2C, a light-emitting layer 206 is formed on the n-type GaN layer 204. The light-emitting layer 206 can have a multi quantum-well structure, comprised of barrier layers made of GaN alternately laminated with well layers made of InGaN (not shown). A GaN barrier layer of the multi quantum-well structure may be formed via feeding N₂, TMGa and NH₃ at a constant temperature of about 740° C., or more generally between about 400-1100° C.; an InGaN well layer of the multi quantum-well structure may be formed via feeding N₂, TMGa, trimethyl indium (TMI) and NH₃.

Referring to FIG. 2D, a process of forming a p-type GaN layer 208 is described. In this embodiment, a metal-organic vapor phase epitaxy growth technique is conducted in a reaction chamber where are introduced N₂ carrier gas and reactive compounds including TMGa or TEGa and ammonia NH₃, with Mg, Zn, Cd or like elements used as p-type impurity. This growth process is conducted at a temperature above about 400° C., for example at about 740° C., at a pressure of about 500 mbar for about 120 seconds. Once the growth process is completed, the formed layer 208 is an as-grown active p-type GaN layer. No annealing step or like activation processes is necessary to activate the p-type GaN layer 208.

Should the p-type layer 208 be made of a compound other than GaN, such as InGaN, AlGaN and the like, the chemical mixture can include additional reactive compounds such as trimethyl indium, trimethyl aluminum and the like.

Referring to FIG. 2E, a transparent conducting layer 210 is formed on the p-type GaN layer 208. The transparent conducting layer 210 is made of a metal oxide such as indium-tin oxide or the like.

Referring to FIG. 2F, a portion of the stack comprised of the n-type GaN layer 204, light-emitting layer 206, p-type GaN layer 208 and transparent conducting layer 210 is etched down until an area 212 of the n-type GaN layer 204 is exposed. Contact pads 214 are then formed on an area of the transparent conducting layer 210 and the area 212 of the n-type GaN layer 204, respectively. A light-emitting device is thereby completed without requiring an activation process of the p-type GaN layer.

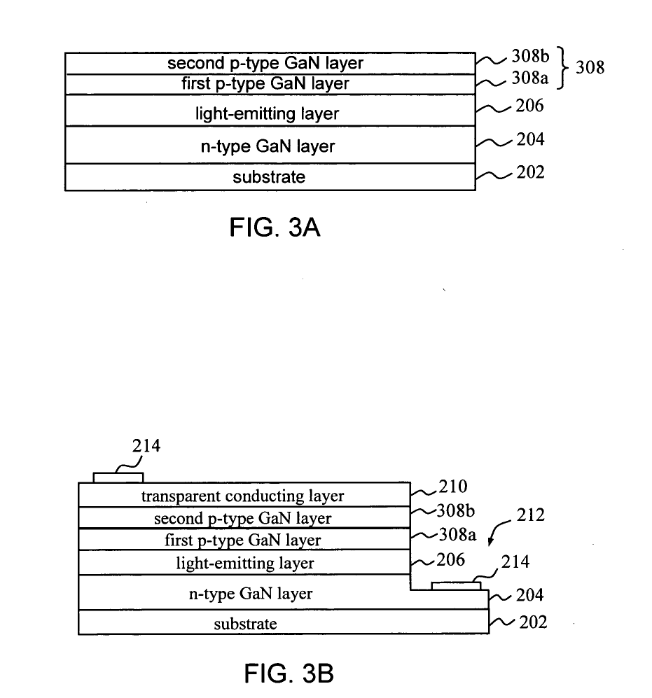

FIG. 3A illustrates a process of forming a p-type GaN layer without requiring an activation step according to another embodiment of the invention. In this variant embodiment, two different compositions of carrier gas are sequentially fed in the reaction chamber to form an as-grown active p-type GaN layer. The specific sequence of feeding the carrier gases described herein is only for purposes of illustration, and alternatively can be changed to any order that can adequately form an as-grown active p-type layer.

On the light-emitting layer 206, a first p-type GaN layer 308a is grown by feeding H₂ carrier gas and reactive compounds including TMGa or TEGa, and NH₃, with Mg p-type impurity. This growth process is conducted at a temperature above about 400° C., for example at about 740° C., at a pressure of about 500 mbar. Subsequently, a second p-type GaN layer 308b is grown on the first p-type GaN layer 308a by feeding N₂ instead of H₂ as carrier gas along with the same reactive compounds previously fed to form the first p-type GaN layer 308a. The pressure and temperature conditions implemented for the second p-type GaN layer 308b may be similar to those used for the first p-type GaN layer 308a. Under an N₂ environment, the p-type GaN layer 308b is grown active and the previously formed p-type GaN layer 308a can be concurrently activated. The final p-type GaN layer structure 308 thereby grown is active and does not require any additional activation steps.

Referring to 3B, the transparent conducting layer 210 may be formed on the p-type GaN layer 308, and etching may be conducted to complete the structure of a light-emitting device.

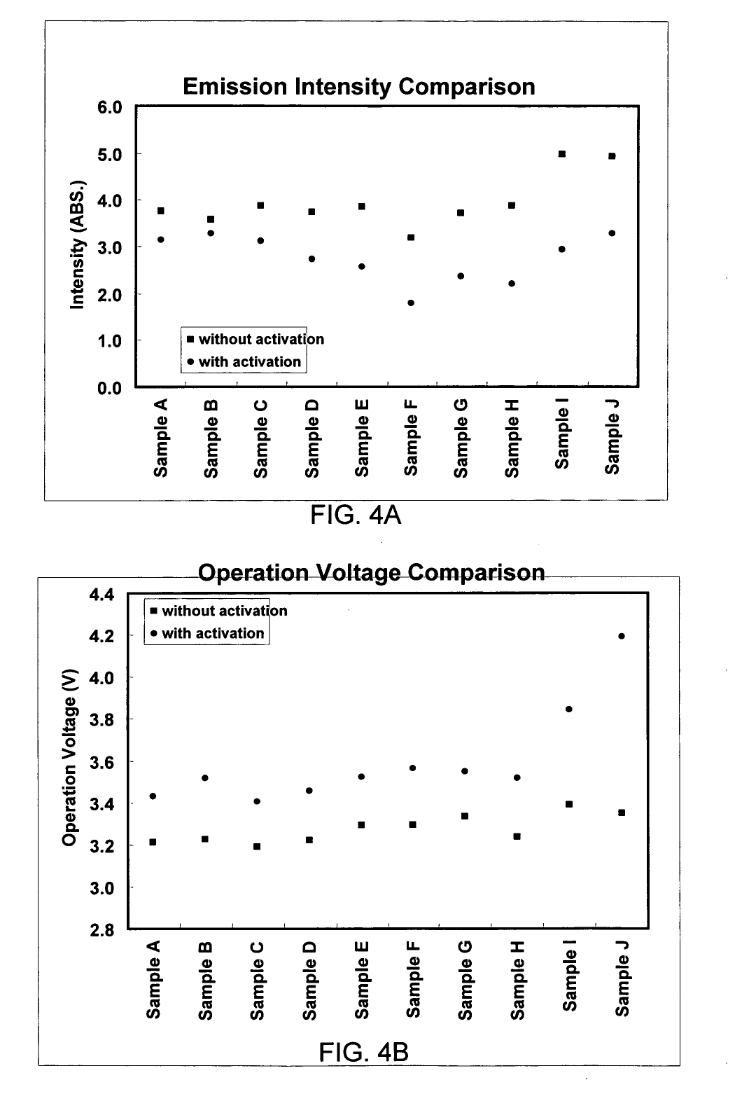

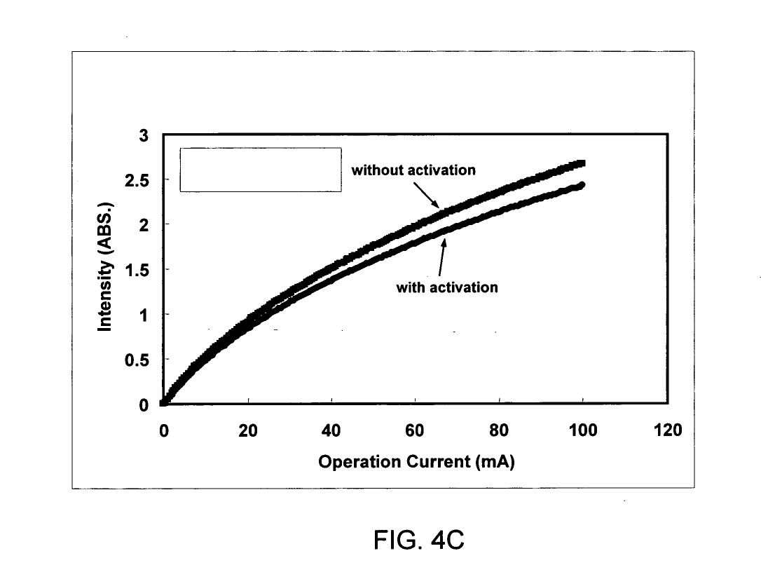

FIGS. 4A˜4C are schematic graphs illustrating results of performance tests conducted on representative samples of light-emitting devices fabricated respectively with and without activation process applied on the p-type GaN layer. In FIGS. 4A and 4B, samples A-J are ten different sample wafers, and each sample wafer is divided into two halves, a first halve including light-emitting devices formed according to a conventional method with an annealing step applied to the p-type GaN layer, and a second halve including light-emitting devices formed according to this invention without annealing. The light-emitting devices formed in the first and second halves have the same layer structure as exemplary described in FIG. 2F, and differ principally in that the manufacturing process conducted in the second wafer halve additionally includes an activation process performed at a temperature of about 700° C. to 800° C. for about 5 to 10 minutes to activate the p-type GaN layer of the light-emitting devices.

As shown in FIGS. 4A and 4B, compared to light-emitting devices manufactured according to a conventional method with an annealing step, light light-emitting devices fabricated according to the invention without an activation process operate with a lower operation voltage and emit a higher light intensity.

FIG. 4C plots light intensity curves varying in function of the operation current. The two light intensity curves are obtained for light-emitting devices fabricated respectively with and without an activation process applied to the p-type GaN layer. As shown, the light intensity increases along with the increase of the operation voltage. However, the light intensity of light-emitting devices fabricated without an activation process is higher than that emitted from the light-emitting device with an activation process.

The above test results show that a light-emitting device fabricated according this invention without an activation process to the p-type GaN layer exhibits better performance than the conventional light-emitting device fabricated with an activation step. By eliminating the need of an activation process, this invention advantageously reduces the thermal cost of the manufacture process, and also shortens the processing time.

It will be appreciated that the inventive features described herein may be generally applicable to any embodiments of light-emitting devices and other semiconductor devices that conventionally require an annealing step to activate doped impurities. Further, the inventive features described herein may be implemented to form as-grown active p-type layers made of compounds different from GaN-based compounds.

Realizations in accordance with the present invention thus have been described in the context of particular embodiments. These embodiments are meant to be illustrative and not limiting. Many variations, modifications, additions, and improvements are possible. Accordingly, plural instances may be provided for components described herein as a single instance. Structures and functionality presented as discrete components in the exemplary configurations may be implemented as a combined structure or component. These and other variations, modifications, additions, and improvements may fall within the scope of the invention as defined in the claims that follow.

1. A process of forming an active p-type III-V nitride compound layer, comprising:
introducing N₂ carrier gas in a reaction chamber where is placed a substrate having a top surface defined by a light-emitting layer structure, wherein the reaction chamber is at a reaction temperature; and
introducing at least one source compound of a group III element, one nitrogen source compound, and a p-type impurity in the reaction chamber, to trigger a chemical reaction that deposits an active p-type III-V nitride compound layer on the light-emitting layer structure.

2. The process of claim 1, wherein the reaction temperature is above about 400° C.

3. The process of claim 1, wherein the at least one source compound of a group III element includes trimethyl gallium, triethyl gallium, trimethyl indium, trimethyl aluminum, or the like.

4. The process of claim 1, wherein the nitrogen source compound includes ammonia NH₃.

5. The process of claim 1, wherein the p-type impurity includes Mg, Zn, Cd or the like.

6-16. (canceled)

17. The process of claim 1, wherein the light-emitting layer structure includes a multi quantum-well structure.

18. A process of forming an active p-type III-V nitride compound layer, comprising:
placing a substrate in a reaction chamber; and
introducing a carrier gas, at least one source compound of a group III element, one nitrogen source compound, and a p-type impurity in the reaction chamber to trigger a chemical reaction that deposits an active p-type III-V nitride compound layer over the substrate;
wherein the chemical reaction depositing the active p-type III-V nitride compound layer singly uses N₂ as the carrier gas.

19. The process of claim 18, wherein the reaction temperature is above about 400° C.

20. The process of claim 18, wherein the at least one source compound of a group III element includes trimethyl gallium, triethyl gallium, trimethyl indium, trimethyl aluminum, or the like.

21. The process of claim 18, wherein the nitrogen source compound includes ammonia NH₃.

22. The process of claim 18, wherein the p-type impurity includes Mg, Zn, Cd or the like.

23. The process of claim 18, wherein the substrate placed in the reaction chamber has a top surface defined by a light-emitting layer structure.

24. The process of claim 23, wherein the light-emitting layer structure includes a multi quantum-well structure.
